(19) United States
(12) Patent Application Publication
(10) Pub. No.: US 2025/0385235 A1
(43) Pub. Date: Dec. 18, 2025

(54) INTERPOSERS FOR DOUBLE-SIDED MEMORY BONDING

(71) Applicant: Micron Technology, Inc., Boise, ID (US)

(72) Inventor: Yeonseung Jung, Meridian, ID (US)

(21) Appl. No.: 19/228,476

(22) Filed: Jun. 4, 2025

Related U.S. Application Data
(60) Provisional application No. 63/659,738, filed on Jun. 13, 2024.

(51) Int. Cl. H01L 25/18; H01L 21/48; H01L 23/00; H01L 23/367; H01L 23/528; H01L 23/538; H10B 80/00; H10D 80/30

(52) U.S. Cl. CPC H01L 25/18; H01L 21/4875; H01L 23/3677; H01L 23/528; H01L 23/5386; H01L 24/08; H01L 24/80; H10B 80/00; H10D 80/30; H01L 2224/08145; H01L 2224/08225; H01L 2224/80895; H01L 2224/80896; H01L 2225/06524; H01L 2225/06589; H01L 2924/1431; H01L 2924/14361

(57) ABSTRACT

Methods, systems, and devices for interposers for double-sided memory bonding are described. A semiconductor system may implement stacks of memory dies on two sides of an interposer. For example, one or more first stacks of memory dies may be bonded to the interposer on a first side, and one or more second stacks of memory dies may be bonded to the interposer on a second side of the interposer opposite the first side. In some implementations, a processor may also be bonded to the interposer on the first side. As such, the semiconductor system may implement additional stacks of memory dies without being limited by a height of the stack, while supporting a heat sink to be bonded with a surface of the one or more first stacks of memory dies and a surface of the processor.

### CROSS REFERENCE

The present Application for Patent claims priority to U.S. Patent Application No. 63/659,738 by Jung, entitled “INTERPOSERS FOR DOUBLE-SIDED MEMORY BONDING,” filed Jun. 13, 2024, which is assigned to the assignee hereof, and which is expressly incorporated by reference in its entirety herein.

### TECHNICAL FIELD

The following relates to one or more semiconductor systems including interposers for double-sided memory bonding.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports interposers for double-sided memory bonding in accordance with examples as disclosed herein.

FIG. 2 shows an example of a system that supports interposers for double-sided memory bonding in accordance with examples as disclosed herein.

FIGS. 3, 4, 5A, and 5B show examples of assemblies that support interposers for double-sided memory bonding in accordance with examples as disclosed herein.

FIGS. 6 and 7 show flowcharts illustrating methods that support interposers for double-sided memory bonding in accordance with examples as disclosed herein.

### DETAILED DESCRIPTION

Some semiconductor systems (e.g., memory systems, processor systems) may include a stack of semiconductor components (e.g., semiconductor dies), which may include one or more memory dies (e.g., array dies) or one or more stacks of memory dies that are stacked with a logic die that is operable to access a set of memory arrays distributed across the one or more memory dies. Such a stacked architecture may be implemented as part of a high bandwidth memory (HBM) system or a coupled dynamic random access memory (DRAM) system, among other examples, and may support solutions for memory-centric logic, such as graphics processing units (GPUs), among other implementations. In some examples, an HBM system may include one or more memory dies coupled (e.g., bonded, stacked) with a logic die. In some examples, a 3D stacked memory system may be closely coupled (e.g., physically coupled, electrically coupled, directly coupled) with a processor, such as a GPU or other host device, as part of a physical memory map accessible to the processor. A logic die may include various components such as interface blocks (e.g., memory interface blocks, interface circuitry), logic blocks, controllers, processors, and other components. A semiconductor component (e.g., a semiconductor unit, a semiconductor subsystem), such as a logic die, may be formed as a single die with relevant circuitry, or may be formed with multiple die portions (e.g., relatively smaller dies, dies each including a respective subset of components of a logic unit) that may be referred to as “chiplets” (e.g., logic chiplets), among other examples.

In some cases, semiconductor systems may include an interposer (e.g., a silicon interposer) between a processor (e.g., a GPU) and one or more stacks of memory dies (e.g., an HBM stack). However, such semiconductor systems may have limitations regarding a quantity of memory dies that may be included in a stack (e.g., per HBM stack), or limitations associated with an overall height of each stack. For example, integrated semiconductor systems may implement a shared heat sink for the processor and the one or more stacks of memory dies, which may involve the one or more stacks of memory dies having a same or similar (e.g., coplanar) height dimension as the processor relative to the interposer.

In accordance with examples as described herein, a semiconductor system may implement stacks of memory dies on two sides of an interposer (e.g., a semiconductor interposer, a silicon interposer, a molded interposer, a glass substrate interposer). For example, one or more first stacks of memory dies may be bonded with the interposer on a first side, and one or more second stacks of memory dies may be bonded with the interposer on a second side of the interposer opposite the first side. Some implementations may also include a processor (e.g., a GPU) bonded with the interposer on the first side. As such, the semiconductor system may implement additional stacks of memory dies (e.g., the one or more second stacks) without being limited by a height of the stack. For example, a heat sink may be bonded with a surface of the one or more first stacks of memory dies and a surface of the processor, while the one or more second stacks of memory dies may provide additional memory bandwidth for the semiconductor system without increasing the overall height of the stack (e.g., the HBM stack) relative to the processor.

In addition to applicability in memory systems as described herein, techniques for interposers for double-sided memory bonding may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by increasing memory density while preserving a similar height between memory and processor assemblies, which may increase overall memory bandwidths without increasing a size of memory systems, while allowing for cooling of the memory and processor assemblies with a shared heat sink, among other benefits.

Features of the disclosure are illustrated and described in the context of systems and architectures. Features of the disclosure are further illustrated and described in the context of assemblies and flowcharts.

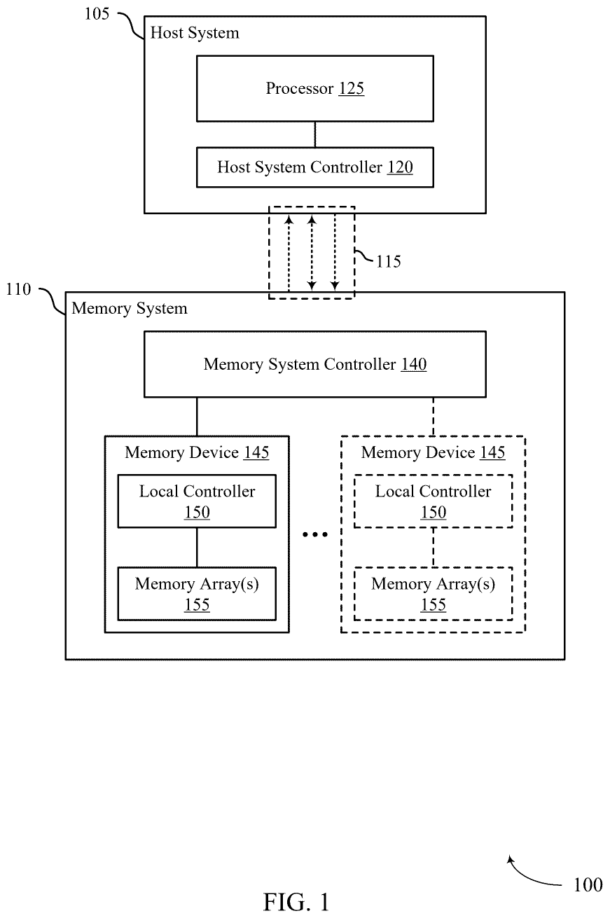

FIG. 1 shows an example of a system 100 that supports interposers for double-sided memory bonding in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, application processing circuitry, one or more processing components) that use memory to execute processes (e.g., applications, functions, computations), any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

In some examples, the system 100 or the host system 105 may include an input component, an output component, or a combination thereof. Input components may include a sensor, a microphone, a keyboard, another processor (e.g., on a printed circuit board), an interface (e.g., a user interface, an interface between other devices), or a peripheral that interfaces with system 100 via one or more peripheral components, among other examples. Output components may include a display, audio speakers, a printing device, another processor on a printed circuit board, or a peripheral that interfaces with the system 100 via one or more peripheral components, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or a combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, portions of a memory die) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

In some examples, at least a portion of the system 100 may implement a stacked semiconductor architecture in which multiple semiconductor dies are physically and communicatively coupled (e.g., directly coupled, bonded). For example, at least one of the memory arrays 155 of a memory device 145 may be formed using one or more semiconductor dies (e.g., a single memory die, a stack of multiple memory dies), which may be stacked over another semiconductor die (e.g., a logic die) that includes at least a portion of a local controller 150. In some examples, a semiconductor die or die assembly may include at least a portion of or all of a local controller 150 and at least a portion of or all of a memory system controller 140, and such a semiconductor die or die assembly may be coupled with one or more memory dies, or one or more stacks of memory dies. In accordance with these and other examples, circuitry for accessing one or more memory arrays 155 (e.g., circuitry of a memory system 110) may be distributed among multiple semiconductor dies of a stack (e.g., a stack of multiple directly-coupled semiconductor dies). For example, a first die may include a set of multiple first interface blocks (e.g., memory interface blocks, instances of first interface circuitry) and one or more second dies may include corresponding second interface blocks, each coupled with a first interface block of the first die, which are each configured to access one or more memory arrays 155 of the second dies. In some examples, the system may include a controller (e.g., a memory controller, an interface controller, a host interface controller, at least a portion of a memory system controller 140) for each set of one or more first interface blocks to support access operations (e.g., to access one or more memory arrays 155) via the set of first interface blocks. In some examples, such a controller may be located in the same first die as the first interface blocks. In some examples, multiple semiconductor dies of a memory system 110 or of a system 100 (e.g., an HBM system including aspects of a memory system 110, a 3D stacked memory system including aspects of a memory system 110 and a host system 105) may include one or more array dies stacked with a logic die (e.g., that includes aspects of the host system 105, that is coupled with another die that includes the host system 105) that includes interface blocks operable to access a set of memory arrays 155 distributed across the one or more second dies.

In some cases, implementations of at least a portion of a system 100 may include an interposer with a processor 125 (e.g., a GPU) and one or more semiconductor dies of a memory system 110. However, such systems 100 may have limitations regarding a quantity of memory dies that may be included in a stack (e.g., an HBM stack), or limitations associated with an overall height of each stack. For example, such a system 100 may implement a shared heat sink for the processor 125 and the one or more semiconductor dies of the memory system 110, which may involve the one or more semiconductor dies having a same or relatively similar (e.g., coplanar) height dimension as the processor 125 relative to the interposer.

In accordance with examples as described herein, a system 100 may include semiconductor components of the memory system 110 bonded on two sides of an interposer. For example, one or more first semiconductor dies may be bonded to the interposer on a first side, and one or more second semiconductor dies may be bonded to the interposer on a second side of the interposer opposite the first side. In some implementations, a processor 125 may also be bonded to the interposer on the first side As such, the system 100 may include additional semiconductor dies without being limited to stacking the semiconductor dies on a same side as the processor 125. For example, a heat sink may be bonded with a surface of the one or more first semiconductor dies and a surface of the processor 125, while the one or more second semiconductor dies may provide additional memory bandwidth for the semiconductor system without increasing the overall height of the stack (e.g., the HBM stack) on the first side of the interposer relative to the processor.

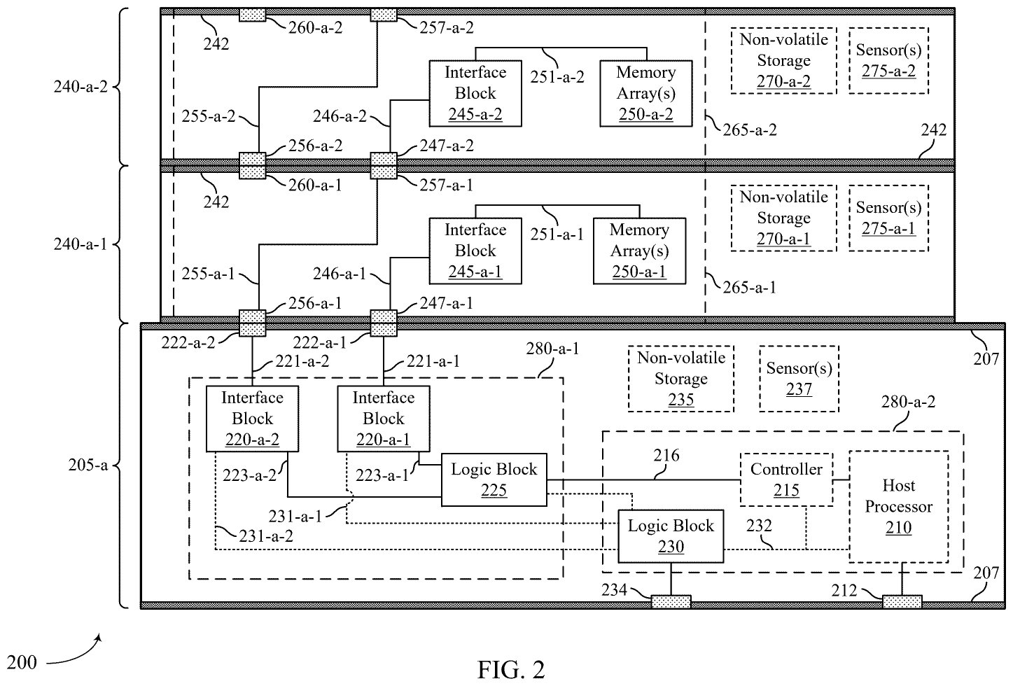

FIG. 2 shows an example of a system 200 (e.g., a semiconductor system, a system of coupled semiconductor dies, an HBM system, a 3D stacked memory system) that supports interposers for double-sided memory bonding in accordance with examples as disclosed herein. The system 200 illustrates an example of a die 205 (e.g., a die 205-a, a semiconductor die, a logic die, a processor die, a host die, a logic unit) that is coupled with one or more dies 240 (e.g., dies 240-a-1 and 240-a-2, semiconductor dies, memory dies, array dies, memory units). A die 205 or a die 240 may be formed using a respective semiconductor substrate (e.g., a substrate of crystalline semiconductor material such as silicon, germanium, silicon-germanium, gallium arsenide, or gallium nitride), or a silicon-on-insulator (SOI) substrate (e.g., silicon-on-glass (SOG), silicon-on-sapphire (SOS)), or epitaxial semiconductor materials formed on another substrate, among other examples. Although the illustrated example of a system 200 includes two dies 240, a system 200 in accordance with the described techniques may include any quantity of one or more dies 240 (e.g., 8, 12, 16, or more dies 240) coupled with a die 205, among other dies of a stack or other coupled layout. Further, although non-limiting examples of the system 200 herein are generally described in terms of applicability to memory systems, memory sub-systems, memory devices, or a combination thereof, examples of the system 200 are not so limited. For example, aspects of the present disclosure may be applied as well to any computing system, computing sub-system, processing system, processing sub-system, component, device, structure, or other types of systems or sub-systems used for applications such as data collecting, data processing, data storage, networking, communication, power, artificial intelligence, system-on-a-chip, control, telemetry, sensing and monitoring, digital entertainment, or any combination thereof.

The system 200 illustrates an example of interface circuitry between a host and memory (e.g., via a host interface, via a physical host interface) that is implemented in (e.g., divided between) multiple semiconductor dies (e.g., a stack of directly-coupled dies). For example, the die 205-a may include a set of one or more interface blocks 220 (e.g., interface blocks 220-a-1 and 220-a-2, memory interface blocks), and each die 240 may include a set of one or more interface blocks 245 (e.g., access interface blocks) and one or more memory arrays 250 (e.g., die 240-a-1 including an interface block 245-a-1 coupled with a set of one or more memory arrays 250-a-1, die 240-a-2 including an interface block 245-a-2 coupled with a set of one or more memory arrays 250-a-2). The memory arrays 250 may be examples of memory arrays 155, and may include memory cells of various architectures, such as RAM, DRAM, SDRAM, SRAM, FeRAM, MRAM, RRAM, PCM, chalcogenide, NOR, or NAND memory cells, or any combination thereof.

Although the example of system 200 is illustrated with one interface block 245 included in each die 240, a die 240 in accordance with the described techniques may include any quantity of one or more interface blocks 245, each coupled with a respective set of one or more memory arrays 250, and each coupled with an interface block 220 of a die 205. Thus, the interface circuitry of a system 200 may include one or more interface blocks 220 of a die 205, with each interface block 220 being coupled with (e.g., in communication with) one or more interfaces block 245 of a die 240 (e.g., external to the die 205). In some examples, a coupled combination of an interface block 220 and an interface block 245 (e.g., coupled via a bus associated with one or more channels, such as one or more data channels, one or more control channels, one or more clock channels, one or more pseudo-channels, or a combination thereof) may include or be referred to as a data path associated with a respective set of one or more memory arrays 250.

In some implementations, a die 205 may include a host processor 210. A host processor 210 may be an example of a host system 105, or a portion thereof (e.g., a processor 125, aspects of a host system controller 120, or both). The host processor 210 may be configured to perform operations that implement storage of the memory arrays 250 (e.g., to support an application or other function of a host system 105, which may request access to the memory arrays 250). For example, the host processor 210 may receive data read from the memory arrays 250, or may transmit data to be written to the memory arrays 250, or both (e.g., in accordance with an application or other operations of the host processor 210). Additionally, or alternatively, a host processor 210 may be external to a die 205 (e.g., in HBM implementations), such as in another semiconductor die or other component that is coupled with (e.g., communicatively coupled with, directly coupled with, bonded with, coupled via another intervening component) the die 205 via one or more contacts 212 (e.g., externally-accessible terminals of the die 205).

A host processor 210 may be configured to communicate (e.g., transmit, receive) signaling with interface blocks 220 via a host interface 216 (e.g., a physical host interface), which may implement aspects of channels 115. For example, a host interface 216 may be configured in accordance with an industry standard, which may define channels, commands, clocking, and deterministic responses and timing, among other characteristics of the host interface 216. In some examples, a host interface 216 may provide a communicative coupling between physical or functional boundaries of a host system 105 and a memory system 110. For example, the host processor 210 may be configured to communicate access signaling (e.g., control signaling, access command signaling, data signaling, configuration signaling, clock signaling) via a host interface 216 to support access operations (e.g., read operations, write operations) on the memory arrays 250, among other operations. Although the example of system 200 includes a single host interface 216, a system in accordance with the described techniques may include any quantity of one or more host interfaces 216 for accessing memory arrays 250 of the system.

In some examples, a respective host interface 216 may be coupled between a set of one or more interface blocks 220 (e.g., interface blocks 220-a-1 and 220-a-2) and a respective controller 215. A controller 215 may be an example of control circuitry (e.g., memory controller circuitry, host interface control circuitry) associated with a host system 105, and may be associated with implementing respective instances of one or more aspects of a host system controller 120, or of a memory system controller 140, or a combination thereof. For example, a controller 215 may be operable to respond to indications (e.g., requests, commands) from the host processor 210 to access one or more memory arrays 250 in support of a function or application of the host processor 210, to transmit associated commands (e.g., for one or more interface blocks 220) to access the one or more memory arrays 250, and to communicate data (e.g., write data, read data) with the host processor 210, among other functions.

In some examples, one or more controllers 215 may be implemented in a die 205 (e.g., the same die that includes one or more interface blocks 220, in a 3D stacked memory implementation in accordance with a command and address protocol) whether a host processor 210 is included in the die 205, or is external to the die 205. In some other examples, controllers 215 or associated circuitry or functionality may be implemented external to a die 205 (e.g., in another die, not shown, coupled with respective interface blocks 220 via respective terminals for each of the respective host interfaces 216, in an HBM implementation), which may be in the same die as or a different die from a die that includes a host processor 210. An interface block 220 may be operable via a single controller 215, or by one or more of a set of multiple controllers 215 (e.g., in accordance with a controller multiplexing scheme). In some other examples, aspects of one or more controllers 215 may be included in the host processor 210 (e.g., as a memory interface of the host processor 210, as a memory interface of a host system 105).

Although, in some examples, a controller 215 may be directly coupled with one or more interface blocks 220 (not shown), in some other examples, a controller 215 (e.g., a host interface 216) may be coupled with a set of multiple interface blocks 220 via a logic block 225 (e.g., logic circuitry for a channel set, logic circuitry for a host interface 216, multiplexing circuitry). For example, the logic block 225 may be coupled with the interface block 220-a-1 via a bus 223-a-1 and coupled with the interface block 220-a-2 via a bus 223-a-2. A controller 215 and one or more corresponding interface blocks 220 and may communicate (e.g., collaborate) using the host interface 216 via a logic block 225 to perform one or more operations (e.g., scheduling operations, access operations, operations initiated by a host processor 210) associated with accessing a corresponding set of one or more memory arrays 250.

In some examples, a logic block 225, a controller 215, or a host interface 216, or a combination thereof may be associated with a “channel set” that corresponds to multiple memory arrays 250 (e.g., for parallel or otherwise coordinated access of the multiple memory arrays 250). For example, such a channel set may be associated with multiple memory arrays 250 accessed via a single interface block 245, or multiple memory arrays 250 each accessed via a respective one of the interface blocks 245, or multiple memory arrays 250 each accessed via a respective one of the interface blocks 220, any of which may be associated with signaling via a single logic block 225, via a single host interface 216, or via a single controller 215. These and other configurations for implementing one or more channel sets in a system may support various techniques for parallelism and high bandwidth data transfer, memory management operations, repair and replacement techniques, or power and thermal distribution, among other techniques that leverage the described coupling of components and interfaces among multiple semiconductor dies (e.g., in accordance with a high bandwidth configuration of the system 200, in accordance with a closely-coupled configuration of the system 200). In some examples, such techniques may be implemented (e.g., at or using a logic block 225) in a manner that is transparent to the host interface 216 or other aspects of a host system 105.

In some examples, a host interface 216 may include a respective set of one or more signal paths for each logic block 225 or interface block 220, such that the host processor 210 may communicate with each logic block 225 or interface block 220 via its corresponding set of signal paths (e.g., in accordance with a selection of the corresponding set to perform access operations via a logic block 225 or interface block 220 that is selected by the host processor 210). Additionally, or alternatively, a host interface 216 may include one or more signal paths that are shared among multiple logic blocks 225 (not shown) or interface blocks 220, and a logic block 225, an interface block 220, or a host processor 210, or any of these may interpret, ignore, respond to, or inhibit response to signaling via shared signal paths of the host interface 216 based on a logical indication (e.g., an addressing indication associated with the logic block 225 or interface block 220, an interface enable signal, or an interface select signal, which may be provided by the host processor 210, the corresponding logic block 225, or the corresponding interface block 220 depending on signaling direction).

In some examples, a host processor 210 may determine to access an address (e.g., a logical address of a memory array 250, a physical address of a memory array 250, an address of a logic block 225, an address of an interface block 220, an address of a host interface 216, in response to an application of or supported by the host processor 210), and determine which controller 215 to transmit access signaling to for accessing the address (e.g., a controller 215, logic block 225, or interface block 220 corresponding to the address). In some examples, the address may be associated with a row of memory cells of the memory array 250, a column of memory cells of the memory array 250, or both. The host processor 210 may transmit access signaling (e.g., one or more access signals, one or more access commands) to the determined controller 215 and, in turn, the determined controller 215 may transmit access signaling to the corresponding logic block 225 or interface block 220 (e.g., in accordance with a command and address protocol). The corresponding interface block 220 may subsequently transmit access signaling to the coupled interface block 245 to access the determined address (e.g., of a corresponding memory array 250).

A die 205 may also include a logic block 230 (e.g., a shared logic block, a central logic block, common logic circuitry, evaluation circuitry, memory system configuration circuitry, memory system management circuitry), which may be configured to communicate (e.g., transmit, receive) signaling with the logic blocks 225, the interface blocks 220, or both of the die 205. In some cases, a logic block 230 may be configured to communicate information (e.g., commands, instructions, indications, data) with one or more logic blocks 225 or interface blocks 220 to facilitate operations of the system 200. For example, a logic block 230 may be configured to transmit configuration signaling (e.g., initialization signaling, evaluation signaling, mapping signaling), which may be received by logic blocks 225 or interface blocks 220 to support configuration of the logic blocks 225 or interface blocks 220, or other aspects of operating the dies 240 (e.g., via the respective interface blocks 245). A logic block 230 may be coupled with each logic block 225 and each interface block 220 via a respective bus 231. In some examples, such buses may each include a respective set of one or more signal paths, such that a logic block 230 may communicate with each logic block 225 or each interface block 220 via the respective set of signal paths. Additionally, or alternatively, such buses may include one or more signal paths that are shared among multiple logic blocks 225 or interface blocks 220 (not shown).

In some implementations, a logic block 230 may be configured to communicate (e.g., transmit, receive) signaling with a host processor 210 or one or more controllers 215 (e.g., via a bus 232, via a contact 212 for a host processor 210 or controller 215 external to a die 205), such that the logic block 230 may support an interface between the host processor 210 or one or more controllers 215 and the logic blocks 225 or interface blocks 220. For example, a host processor 210 or a controller 215 may be configured to transmit initialization signaling (e.g., boot commands), or other configuration or operational signaling, which may be received by a logic block 230 to support initialization, configuration, evaluation, or other operations of the logic blocks 225 or interface blocks 220. Additionally, or alternatively, in some implementations, a logic block 230 may be configured to communicate (e.g., transmit, receive) signaling with a component outside the system 200 (e.g., via a contact 234, which may be an externally-accessible terminal of the die 205), such that the logic block 230 may support an interface that bypasses a host processor 210 or controller 215. Additionally, or alternatively, a logic block 230 may communicate with a host processor 210 or a controller 215, and may communicate with one or more memory arrays 250 of one or more dies 240 (e.g., to perform self-test operations for access of memory arrays 250). In some examples, such implementations may support evaluations, configurations, or other operations of the system 200, via one or more contacts 234 that are accessible at a physical interface of the system, during manufacturing, assembly, validation, or other operation associated with the system 200 (e.g., before coupling with a host processor 210, without implementing a host processor 210, for operations independent of a host processor). Additionally, or alternatively, a logic block 230 may implement one or more aspects of a controller 215. For example, a logic block 230 may include or operate as one or more controllers 215 and may perform operations ascribed to a controller 215.

In some examples, respective signals may be routed between a die 205 and one or more dies 240. For example, each interface block 220 may be coupled with at least a respective bus 221 of the die 205, and a respective bus 246 of a die 240, that are configured to communicate signaling with a corresponding interface block 245 (e.g., via one or more associated signal paths). For example, the interface block 220-a-1 may be coupled with the interface block 245-a-1 via a bus 221-a-1 and a bus 246-a-1, and the interface block 220-a-2 may be coupled with the interface block 245-a-2 via a bus 221-a-2 and a bus 246-a-2. In some examples, a die 240 may include a bus that bypasses operational circuitry of the die 240 (e.g., that bypasses interface blocks 245 of a given die 240), such as a bus 255. For example, the interface block 220-a-2 may be coupled with the interface block 245-a-2 of the die 240-a-2 via a bus 255-a-1 of the die 240-a-1, which may bypass interface blocks 245 of the die 240-a-1. Such techniques may be extended for interconnection among more than two dies 240 (e.g., for interconnection via a respective bus 255 of multiple dies 240). In some implementations, at least a portion of a bus 221, a bus 246, or a bus 255, or any combination thereof may include one or more conductors in a redistribution layer (RDL) of a respective die (e.g., above or below a semiconductor substrate of the die). Additionally, or alternatively, in some implementations, at least a portion of a bus 221, a bus 246, or a bus 255, or any combination thereof may include one or more vias that are formed through a semiconductor substrate of a respective die (e.g., as one or more through-silicon vias (TSVs)).

The respective signal paths of buses 221, 246, and 255 may be coupled with one another, from one die to another, via various arrangements of contacts at the surfaces of interfacing dies (e.g., exposed contacts, metal surfaces of the respective dies). For example, the bus 221-a-1 may be coupled with the bus 246-a-1 via a contact 222-a-1 of (e.g., at a surface of) the die 205-a and a contact 247-a-1 of the die 240-a-1, the bus 221-a-2 may be coupled with the bus 255-a-1 via a contact 222-a-2 of the die 205 and a contact 256-a-1 of the die 240-a-1, the bus 255-a-1 may be coupled with the bus 246-a-2 via a contact 257-a-1 of the die 240-a-1 and a contact 247-a-2 of the die 240-a-2, and so on. Although each respective bus is illustrated with a single line, coupled via singular contacts, it is to be understood that each signal path of a given bus may be associated with respective contacts to support a separate communicative coupling via each signal path of the given bus. In some examples, a bus 255 may traverse a portion of a die 240 (e.g., in an in-plane direction, along a direction different from a thickness direction, in a waterfall arrangement, in a staircase arrangement), which may support an arrangement of contacts 222 along a surface of a die 205, among other contacts, being coupled with interface blocks 245 of different dies 240 along a stack direction (e.g., via respective contacts 256 and 257 that are non-overlapping when viewed along a thickness direction).

The interconnection of interfacing contacts may be supported by various techniques. For example, in a hybrid bonding implementation, interfacing contacts may be coupled by a fusion of conductive materials (e.g., electrically conductive materials) of the interfacing contacts (e.g., without solder or other intervening material between contacts). For example, in an assembled condition, the coupling of the die 205-a with the die 240-a-1 may include a conductive material of the contact 222-a-2 being fused with a conductive material of the contact 256-a-1, and the coupling of the die 240-a-1 with the die 240-a-2 may include a conductive material of the contact 257-a-1 being fused with a conductive material of the contact 247-a-2, and so on. In some examples, such coupling may include an inoperative fusion of contacts (e.g., a non-communicative coupling, a physical coupling), such as a fusion of the contact 260-a-1 with the contact 256-a-2, neither of which are coupled with operative circuitry of the dies 240-a-1 or 240-a-2. In some examples, such techniques may be implemented to improve coupling strength or uniformity (e.g., implementing contacts 260, which may not be operatively coupled with an interface block 245 or an interface block 220), or such a coupling may be a byproduct of a repetition of components that, in various configurations, may be operative or inoperative. (e.g., where, for dies 240 with a common arrangement of contacts 256 and 257, contacts 256-a-1 and 257-a-1 provide a communicative path between the interface block 245-a-2 and the interface block 220-a-2, but the contacts 256-a-2 and 257-a-2 do not provide a communicative path between an interface block 245 and an interface block 220).

In some examples, a fusion of conductive materials between dies (e.g., between contacts) may be accompanied by a fusion of other materials at one or more surfaces of the interfacing dies. For example, in an assembled condition, the coupling of the die 205 with the die 240-a-1 may include a dielectric material 207 (e.g., an electrically non-conductive material) of the die 205-a being fused with a dielectric material 242 of the die 240-a-1, and the coupling of the die 240-a-1 with the die 240-a-2 may include a dielectric material 242 of the die 240-a-1 being fused with a dielectric material 242 of the die 240-a-2. In some examples, such dielectric materials may include an oxide, a nitride, a carbide, an oxide-nitride, an oxide-carbide, or other conversion or doping of a substrate material (e.g., a semiconductor substrate material) or other material of the die 205 or dies 240, among other materials that may support such fusion. However, coupling among dies 205 and dies 240 may be implemented in accordance with other techniques, which may implement solder, adhesives, thermal interface materials, and other intervening materials or combinations of materials.

In some examples, dies 240 may be coupled in a stack (e.g., forming a “cube” or other arrangement of dies 240), and one or more of such stacks may subsequently be coupled with a die 205 (e.g., in a stack-to-chip bonding arrangement). In some examples, respective set(s) of one or more dies 240 may be coupled with each die 205 of multiple dies 205 as formed in a wafer (e.g., in a chip-to-wafer bonding arrangement, in a stack-to-wafer bonding arrangement, before cutting the wafer of dies 205), and the dies 205 of the wafer, each coupled with their respective set(s) of dies 240, may be separated from one another (e.g., by cutting at least the wafer of dies 205, by singulation). In some other examples, respective set(s) of one or more dies 240 may be coupled with a respective die 205 after the die 205 is separated from a wafer of dies 205 (e.g., in a chip-to-chip bonding arrangement). In some other examples, a respective set of one or more wafers, each including multiple dies 240, may be coupled in a stack (e.g., in a wafer-to-wafer bonding arrangement). In various examples, such techniques may be followed by separating stacks of dies 240 from the coupled wafers, or the stack of wafers having dies 240 may be coupled with another wafer including multiple dies 205 (e.g., in a second wafer-to-wafer bonding arrangement), which may be followed by separating systems 200 from the coupled wafers. In some other examples, wafer-to-wafer coupling techniques may be implemented by stacking one or more wafers of dies 240 (e.g., sequentially) over a wafer of dies 205 before separation into systems 200, among other examples for forming systems 200.

The buses 221, 246, and 255 may be implemented to provide a configured signaling (e.g., a coordinated signaling, a logical signaling, modulated signaling, digital signaling) between an interface block 220 and a corresponding interface block 245, which may involve various modulation or encoding techniques by a transmitting interface block (e.g., via a driver component of the transmitting interface block). In some examples, such signaling may be supported by (e.g., accompanied by) clock signaling communicated via the respective buses (e.g., in coordination with signal transmission). For example, the buses may be configured to convey one or more clock signals transmitted by the interface block 220 for reception by the interface block 245 (e.g., to trigger signal reception by a latch or other reception component of the interface block 245, to support clocked operations of the interface block 245). Additionally, or alternatively, the buses may be configured to convey one or more clock signals transmitted by the interface block 245 for reception by the interface block 220 (e.g., to trigger signal reception by a latch or other reception component of the interface block 220, to support clocked operations of the interface block 220). Such clock signals may be associated with the communication (e.g., unidirectional communication, bidirectional communication, deterministic communication) of various signaling, such as control signaling, command signaling, data signaling, or any combination thereof. For example, the buses may include one or more signal paths for communications of a data bus (e.g., one or more data channels, a DQ bus, via a data interface of the interface blocks) in accordance with one or more corresponding clock signals (e.g., data clock signals), or one or more signal paths for communications of a control bus (e.g., a command/address (C/A) bus, via a command interface of the interface blocks) in accordance with one or more clock signals (e.g., control clock signals), or any combination thereof.

Interface blocks 220, interface blocks 245, logic blocks 225, and a logic block 230 each may include circuitry (signaling circuitry, multiplexing circuitry, processing circuitry, controller circuitry, logic circuitry, physical components, hardware) in various configurations (e.g., hardware configurations, logic configurations, software or instruction configurations) that support the functionality allocated to the respective block for accessing or otherwise operating a corresponding set of memory arrays 250. For example, interface blocks 220 may include circuitry configured to perform a first subset of operations that support access of the memory arrays 250, and interface blocks 245 may include circuitry configured to perform a second subset of operations that support access of the memory arrays 250. In some examples, the interface blocks 220, the interface blocks 245, and logic blocks 225 may support a functional split or distribution of functionality associated with a memory system controller 140, a local controller 150, or both across multiple dies (e.g., a die 205 and at least one die 240). In some implementations, a logic block 230 may be configured to coordinate or configure aspects of the operations of the interface blocks 220, of the interface blocks 245, of the logic blocks 225, or a combination thereof, and may support implementing one or more aspects of a memory system controller 140. Such operations, or subsets of operations, may include operations performed in response to commands from the host processor 210 or a controller 215, or operations performed without commands from a host processor 210 or a controller 215 (e.g., operations determined by or initiated by a logic block 225, operations determined by or initiated by an interface block 220, operations determined by or initiated by an interface block 245, operations determined by or initiated by a logic block 230), or various combinations thereof.

In some implementations, the system 200 may include one or more instances of non-volatile storage (e.g., non-volatile storage 235 of a die 205, non-volatile storage 270 of one or more dies 240, or a combination thereof). In some examples, a logic block 230, logic blocks 225, interface blocks 220, interface blocks 245, or a combination thereof may be configured to communicate signaling with one or more instances of non-volatile storage. For example, a logic block 230, logic blocks 225, interface blocks 220, or interface blocks 245 may be coupled with one or more instances of non-volatile storage via one or more buses (not shown), or respective contacts (not shown), where applicable, which may each include one or more signal paths operable to communicate signaling (e.g., command signaling, data signaling). In some examples, a logic block 230, one or more logic blocks 225, one or more interface blocks 220, one or more interface blocks 245, or a combination thereof may configure one or more operations based on information (e.g., instructions, configurations, parameters) stored in one or more instances of non-volatile storage. Additionally, or alternatively, in some examples, a logic block 230, one or more logic blocks 225, one or more interface blocks 220, one or more interface blocks 245, or a combination thereof may write information (e.g., configuration information, evaluation information) to be stored in one or more instances of non-volatile storage. In some examples, such non-volatile storage may include fuses, antifuses, or other types of one-time programmable storage elements, or any combination thereof.

In some implementations, the system 200 may include one or more sensors (e.g., one or more sensors 237 of a die 205, one or more sensors 275 of one or more dies 240, or a combination thereof). In some implementations, a logic block 230, logic blocks 225, interface blocks 220, interface blocks 245, or a combination thereof may be configured to receive one or more indications based on measurements of one or more sensors of the system 200. For example, a logic block 230, logic blocks 225, interface blocks 220, or interface blocks 245 may be coupled with one or more sensors via one or more buses (not shown), or respective contacts (not shown). Such sensors may include temperature sensors, current sensors, voltage sensors, counters, and other types of sensors. In some examples, a logic block 230, one or more logic blocks 225, one or more interface blocks 220, one or more interface blocks 245, or a combination thereof may configure one or more operations based on output of the one or more sensors. For example, a logic block 230 may configure one or more operations of logic blocks 225 or interface blocks 220 based on signaling (e.g., indications, data) received from the one or more sensors. Additionally, or alternatively, a logic block 225 or an interface block 220 may generate access signaling for transmitting to a corresponding interface block 245 based on one or more sensors.

In some examples, circuitry of logic blocks 225, interface blocks 220, interface blocks 245, or a logic block 230, or any combination thereof may include components (e.g., transistors) formed at least in part from doped portions of a substrate of the respective die. In some examples, a substrate of a die 205 may have characteristics (e.g., materials, material characteristics, physical shapes or dimensions) that are different from those of a substrate of a die 240. Additionally, or alternatively, in some examples, transistors formed from a substrate of a die 205 may have characteristics (e.g., manufacturing characteristics, performance characteristics, physical shapes or dimensions) that are different from transistors formed from a substrate of a die 240 (e.g., in accordance with different transistor architectures, in accordance with different transistor designs).

In some examples, the interface blocks 220 may support a layout for one or more components within the interface blocks 220. For example, the layout may include pairing components to share an access port (e.g., a command port, a data port). Further, in some examples, the layout may support interfaces for a controller 215 (e.g., a host interface 216) that are different from interfaces for an interface block 245 (e.g., via the buses 221). For instance, a host interface 216 may be synchronous and have separate channels for read and write operations, while an interface between an interface block 220 and one or more interface blocks 245 may be asynchronous and support both read and write operations with the same channel. In some examples, signaling of a host interface 216 may be implemented with a deterministic timing (e.g., deterministic between a controller 215 and a logic block 225 or one or more interface blocks 220), which may be associated with a configured timing between a first signal and a responsive second signal. In some examples, signaling between an interface block 220 and one or more interface blocks 245 may be implemented with a timing that is different from timing of a host interface 216 (e.g., in accordance with a different clock frequency, in accordance with a timing offset, such as a phase offset), which may be deterministic or non-deterministic.

A die 240 may include one or more units 265 (e.g., modules) that are separated from a semiconductor wafer having a pattern (e.g., a two-dimensional pattern) of units 265. Although each die 240 of the system 200 is illustrated with a single unit 265 (e.g., unit 265-a-1 of die 240-a-1, unit 265-a-2 of die 240-a-2), a die 240 in accordance with the described techniques may include any quantity of units 265, which may be arranged in various patterns (e.g., sets of one or more units 265 along a row direction, sets of one or more units 265 along a column direction, among other patterns). Each unit 265 may include at least the circuitry of a respective interface block 245, along with memory array(s) 250, a bus 251, a bus 246, and one or more contacts 247 corresponding to the respective interface block 245. In some examples, where applicable, each unit 265 may also include one or more buses 255, contacts 256, contacts 257, or contacts 260 (e.g., associated with a respective interface block 245 of a unit 265 of a different die 240), which may support various degrees of stackability or modularity among or via units 265 of other dies 240. Although examples of non-volatile storage 270 and sensors 275 are illustrated outside units 265, in some other examples, non-volatile storage 270, sensors 275, or both may additionally, or alternatively, be included in units 265.

In some examples, the interface blocks 220 may include circuitry configured to receive first access command signaling (e.g., from a host processor 210, from a controller 215, from a logic block 225, via a host interface 216, via one or more contacts 212 from a host processor 210 or controller 215 external to a die 205, based on a request from a host application), and to transmit second access command signaling to the respective (e.g., coupled) interface block 245 based on (e.g., in response to) the received first access command signaling. The interface blocks 245 may accordingly include circuitry configured to receive the second access command signaling from the respective interface block 220 and, in some examples, to access a respective set of one or more memory arrays 250 based on (e.g., in response to) the received second access command signaling. In various examples, the first access command signaling may include access commands that are associated with a type of operation (e.g., a read operation, a write operation, a refresh operation, a memory management operation), which may be associated with an indication of an address of the one or more memory arrays 250 (e.g., a logical address, a physical address). In some examples, the first access command signaling may include an indication of a logical address associated with the memory arrays 250, and circuitry of an interface block 220 may be configured to generate the second access command signaling to indicate a physical address associated with the memory arrays 250 (e.g., a row address, a column address, using a logical-to-physical (L2P) table or other mapping or calculation functionality of the interface block 220).

In some examples, to support write operations of the system 200, circuitry of the interface blocks 220 may be configured to receive (e.g., from a host processor 210, from a controller 215, from a logic block 225) first data signaling associated with the first access command signaling, and to transmit second data signaling (e.g., associated with second access command signaling) based on received first access command signaling and first data signaling. The interface blocks 245 may accordingly be configured to receive second data signaling, and to write data to one or more memory arrays 250 (e.g., in accordance with an indicated address associated with the first access command signaling) based on the received second access command signaling and second data signaling. In some examples, the interface blocks 220 may include an error control functionality (e.g., error detection circuitry, error correction circuitry, error correction code (ECC) logic, an ECC engine) that supports the interface blocks 220 generating the second data signaling based on performing an error control operation using the received first data signaling (e.g., detecting or correcting an error in the first data signaling, determining one or more parity bits to be conveyed in the second data signaling and written with the data).

In some examples, to support read operations of the system 200, circuitry of the interface blocks 245 may be configured to read data from the memory arrays 250 based on received second access command signaling, and to transmit first data signaling based on the read data. The interface blocks 220 may accordingly be configured to receive first data signaling, and to transmit second data signaling (e.g., to a host processor 210, to a controller 215, to a logic block 225) based on the received first data signaling. In some examples, the interface blocks 220 may include an error control functionality that supports the interface blocks 220 generating the second data signaling based on performing an error control operation using the received first data signaling (e.g., detecting or correcting an error in the first data signaling, which may include a calculation involving one or more parity bits received with the first data signaling).

In some examples, access command signaling that is transmitted to the interface blocks 245, among other signaling, may be generated (e.g., based on access command signaling received from a host processor 210, based on initiation signaling received from a host processor 210, without receiving or otherwise independent from signaling from a host processor 210) in accordance with various determination or generation techniques configured at the interface blocks 220 or the logic blocks 225 (e.g., based on a configuration for accessing memory arrays 250 that is modified at the interface blocks 220 or the logic blocks 225). In some examples, such techniques may involve signaling or other coordination with a logic block 230, a logic block 225, a host processor 210, one or more controllers 215, one or more instances of non-volatile storage, one or more sensors, or any combination thereof. Such techniques may support the interface blocks 220 or logic blocks 225 configuring aspects of the access operations performed on the memory arrays 250 by a respective interface block 245, among other operations. For example, interface blocks 220 or logic blocks 225 may include evaluation circuitry, access configuration circuitry, signaling circuitry, scheduling circuitry, repair circuitry, refresh circuitry, error control circuitry, adverse access (e.g., row hammer) mitigation circuitry, and other circuitry operable to configure operations associated with one or more dies (e.g., operations associated with accessing memory arrays 250 of the dies 240).

In some examples, functionality of a die 205 may be implemented as a semiconductor unit (e.g., a semiconductor system) that is formed with multiple semiconductor die portions (e.g., semiconductor chiplets, relatively smaller semiconductor dies), and each die portion may include respective portions of circuitry associated with the die 205. For example, a unit 280 may represent a portion of the circuitry components included in a die portion (e.g., in a chiplet), and the die portion may include an integer multiple of units 280. In some examples, each semiconductor die portion of a semiconductor unit may include different respective portions of circuitry. As a non-limiting example, a semiconductor unit (e.g., having the functionality of a die 205) may be formed by one or more first die portions having one or more units 280-a-1 and one or more second die portions having one or more units 280-a-2. The one or more units 280-a-1 may include one or more interface blocks 220, a logic block 225, or any combination thereof, and the one or more units 280-a-2 may include a host processor 210, one or more controllers 215, a logic block 230, or any combination thereof.

In some cases, a system 200 may include an interposer coupled with a die 205, a separate die that includes a host processor 210 (e.g., a die that includes one or more units 280-a-2), and one or more dies 240 (e.g., one or more dies that include units 280-a-1), among other implementations. However, such systems may have limitations regarding a quantity of dies (e.g., dies 240) that may be included in a stack (e.g., an HBM stack), or limitations associated with an overall height of each stack. For example, the semiconductor system may implement a shared heat sink for a die that includes a host processor 210 and a stack of one or more dies 240, which may involve the stack of one or more dies 240 having a same or similar (e.g., coplanar) height dimension as the die that includes a host processor 210 relative to the interposer.

In accordance with examples as described herein, the system 200 may implement bonding stacks of one or more dies 240 two sides of an interposer. For example, one or more first stacks of dies 240 may be bonded with the interposer on a first side, and one or more second stacks of dies 240 may be bonded with a second side of the interposer opposite the first side. In some implementations, one or more dies that include one or more host processors 210 (e.g., one or more units 280-a-2) may also be bonded with the interposer on the first side. As such, the system 200 may include additional dies 240 without being limited to stacking them on a same side as a die including a host processor 210. For example, a heat sink may be bonded with a surface of the one or more first stack of dies 240 and a surface of a die that includes a host processor 210, while the one or more second stacks of dies 240 may provide additional memory bandwidth for the semiconductor system without increasing the overall height of the stack (e.g., the HBM stack) on the first side of the interposer relative to the processor.

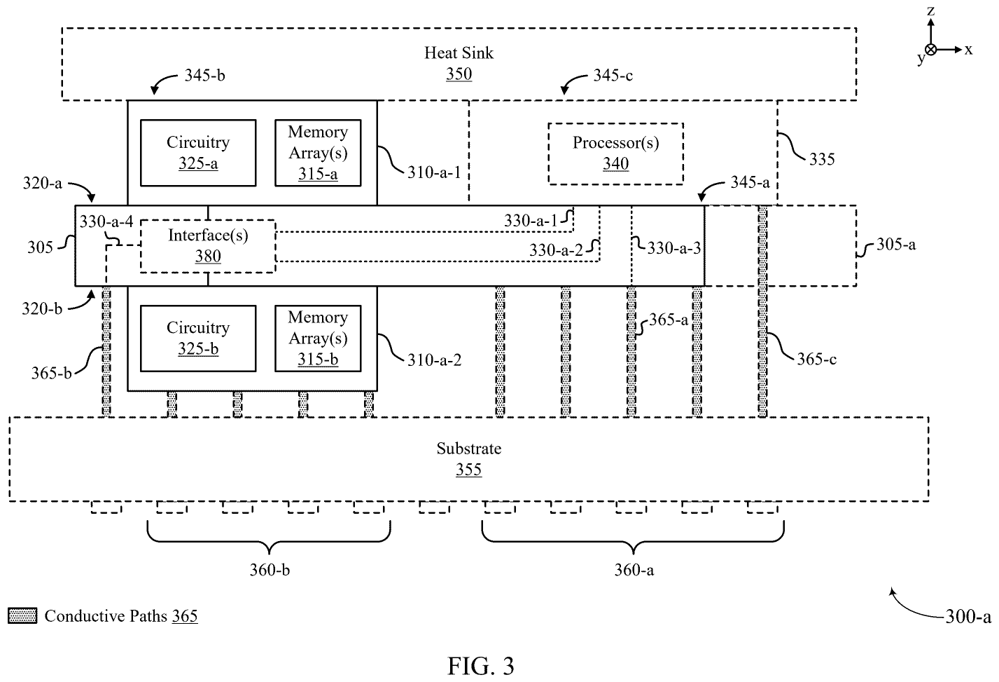

FIG. 3 shows an example of an assembly 300-a that supports interposers for double-sided memory bonding in accordance with examples as disclosed herein. The assembly 300-a may implement aspects of or be implemented by a system 100 or a system 200, as described herein.

The assembly 300-a is an example of a system (e.g., a semiconductor system, a semiconductor assembly) that supports bonding of semiconductor components 310 (e.g., stacks of one or more dies 240, stacks of memory devices 145, HBM stacks, HBM cores, memory stacks) on two sides of an interposer 305 (e.g., a semiconductor interposer, a silicon interposer, a molded interposer, a glass substrate interposer). For example, a semiconductor component 310-a-1 may be bonded with (e.g., coupled with, physically coupled with, electrically coupled with) a side 320-a of the interposer 305, and a semiconductor component 310-a-2 may be bonded with a side 320-b of the interposer 305. By including semiconductor components 310-a on the side 320-a and the side 320-b of the interposer 305, the assembly 300-a may support increased memory bandwidth and density, which may be achieved without increasing the overall height of the semiconductor components 310-a (e.g., along the z-direction) relative to the interposer 305.

A semiconductor component 310 (e.g., semiconductor components 310-a-1 and 310-a-2) may include a set of one or more semiconductor dies (e.g., a memory stack, one die, two dies, four dies, eight dies, twelve dies, sixteen dies, or any other quantity of dies, which may be stacked or otherwise arranged) that support various aspects of memory operations. For example, semiconductor component 310-a-1 may include one or more memory arrays 315-a (e.g., memory arrays 155, memory arrays 250, of a first memory stack) and circuitry 325-a (e.g., aspects of a local controller 150, one or more interface blocks 245, or a combination thereof), Similarly, the semiconductor component 310-a-2 may include one or more memory arrays 315-b (e.g., of a second memory stack) and circuitry 325-b. Each of the semiconductor components 310-a-1 and 310-a-2 may be electrically coupled with the interposer 305 via one or more respective conductive paths. For example, the semiconductor component 310-a-1 and the semiconductor component 310-a-2 may be coupled with one or more interfaces 380 of the interposer 305, which may include an evaluation interface, power connections (e.g., to provide power to semiconductor components 310), one or more physical channels (e.g., communication channels, channels 115, one or more physical host interfaces 216), or a combination thereof. In some examples, each of a set of multiple dies may include a respective array of the memory arrays 315 and respective portions of the circuitry 325 operable to access the respective memory array 315. In some examples, such dies may be stacked (e.g., along the z-direction) as part of the semiconductor component 310.

In some examples, the one or more interfaces 380 may include interface circuitry (e.g., aspects of a memory system controller 140, one or more interface blocks 245, one or more interface blocks 220) operable to access the one or more memory arrays 315-a and the one or more memory arrays 315-b (e.g., to control or otherwise support HBM cores or other memory stacks on both sides of an interposer 305), and communicate signaling to the semiconductor component 335 based on such accessing. For example, the one or more interfaces 380 may include or serve as one or more physical interfaces between the semiconductor component 310-a-1 and the semiconductor component 335 and one or more physical interfaces between the semiconductor component 310-a-2 and the semiconductor component 335 to support the communication of signals (e.g., data signaling, control signaling, command signaling).

In some implementations, the assembly 300-a may also include a semiconductor component 335, which may be an example of aspects of a host system 105 (e.g., a unit 280-a-2, a GPU) or a host system 105. In some examples, the semiconductor component 335 may be bonded with the side 320-a of the interposer 305. The semiconductor component 335 may include one or more processors 340, which may be examples of at least a portion of a host system 105 (e.g., one or more processors 125, one or more host system controllers 120, one or more host processors 210, one or more controllers 215), or one or more other semiconductor dies (e.g., processors), among other processor implementations. In some examples, the semiconductor component 335 (e.g., the one or more processors 340) may be coupled with the semiconductor component 310-a-1 and the semiconductor component 310-a-2 via one or more conductive paths 330-a. For example, the semiconductor component 335 may be coupled with the semiconductor component 310-a-1 via one or more conductive paths 330-a-1 and with the semiconductor component 310-a-2 via one or more conductive paths 330-a-2 (e.g., via the one or more interfaces 380 of the interposer 305). Alternatively, at least some of the conductive paths 330-a-1 and 330-a-2 may be combined into a single (e.g., shared) conductive path 330-a. In some examples, conductive paths 330-a-1 and 330-a-2 may each be examples of one or more physical host interfaces 216.

In some examples, less than an entire surface 345-a (e.g., a surface area along the xy-plane) of the semiconductor component 335 may be bonded with the interposer 305. For example, the semiconductor component 335 may extend farther along the x-direction (e.g., from the semiconductor component 310-a-1) than the interposer 305. In some other examples, the entire surface 345-a of the semiconductor component 335 may be bonded with the interposer 305. For example, the interposer 305 may extend farther along the x-direction than the semiconductor component 335, as shown by the extended interposer 305-a. In some examples, the semiconductor component 310-a-1 and the semiconductor component 310-a-2 may be bonded with the interposer 305 along a same direction (e.g., the x-direction) from the semiconductor component 335.

In some examples, a surface 345-b of the semiconductor component 310-a-1 may have a similar location along the z-direction (e.g., may be coplanar or coplanar within a tolerance) with a surface 345-c of the semiconductor component 335, which may allow for a heat sink 350 to be bonded with both the surface 345-b of the semiconductor component 310-a-1 and the surface 345-c of the semiconductor component 335. Thus, additional semiconductor components 310-a-2 may be included on an opposite side of the interposer 305-a while supporting a heat sink 350 to be bonded to a coplanar surface of the semiconductor component 310-a-1 and semiconductor component 335 to provide heat dissipation for the assembly 300-a.

The assembly 300-a may include a substrate 355 (e.g., a composite conductor substrate, an organic substrate, a semiconductor substrate material, a printed circuit board (PCB), a package substrate), which may include one or more electrical contacts 360. The electrical contacts 360 may be coupled with one or more conductive paths 365, which may be an example of vias (e.g., through mold vias, TSVs). The electrical contacts 360 and the conductive paths 365 may support communications of data signals (e.g., information signaling), control signals, clock signals, or a combination thereof, between the substrate 355 and the semiconductor component 335, the semiconductor component 310-a-1, or the semiconductor component 310-a-2. Additionally, or alternatively, one or more of the electrical contacts 360 and conductive paths 365 may be used to provide power to components of the assembly 300-a.

In some examples, a set of electrical contacts 360-a may be coupled with the semiconductor component 335 via one or more conductive paths 365 (e.g., including at least a conductive path 365-a), and via one or more conductive paths 330-a of the interposer 305 (e.g., at least a conductive path 330-a-3). Additionally, or alternatively, a set of electrical contacts 360-b may be coupled with the semiconductor component 310-a-1 and the semiconductor component 310-a-2 via one or more conductive paths 365, and, in some cases, via one or more conductive paths 330-a of the interposer 305 (e.g., at least a conductive path 330-a-4). In some cases, one or more conductive paths 365, such as a conductive path 365-b, may be configured to provide power to the semiconductor component 310-a-1 and the semiconductor component 310-a-2, for example, via the conductive path 330-a-4 of the interposer 305 (e.g., directly or via the one or more interfaces 380).

In some examples, such as in cases where the interposer 305 extends farther than the semiconductor component 335 in the x-direction, the semiconductor component 335 may be coupled with the substrate 355 via one or more of the conductive paths 365, such as a conductive path 365-c, which do not intersect the interposer 305. The quantity of conductive paths 365 and conductive paths 330 shown in FIG. 3 are exemplary and, in some examples, the assembly 300-a may include different quantities of conductive paths 365 and conductive paths 330, among other features.

Accordingly, by bonding semiconductor components 310-a on the side 320-a and the side 320-b of the interposer 305, the assembly 300-a may support increased memory capacity as well as bandwidth without increasing the overall height of the stack semiconductor components 310-a (e.g., in the z-direction) relative to the semiconductor component 335 and supporting the use of the heat sink 350.

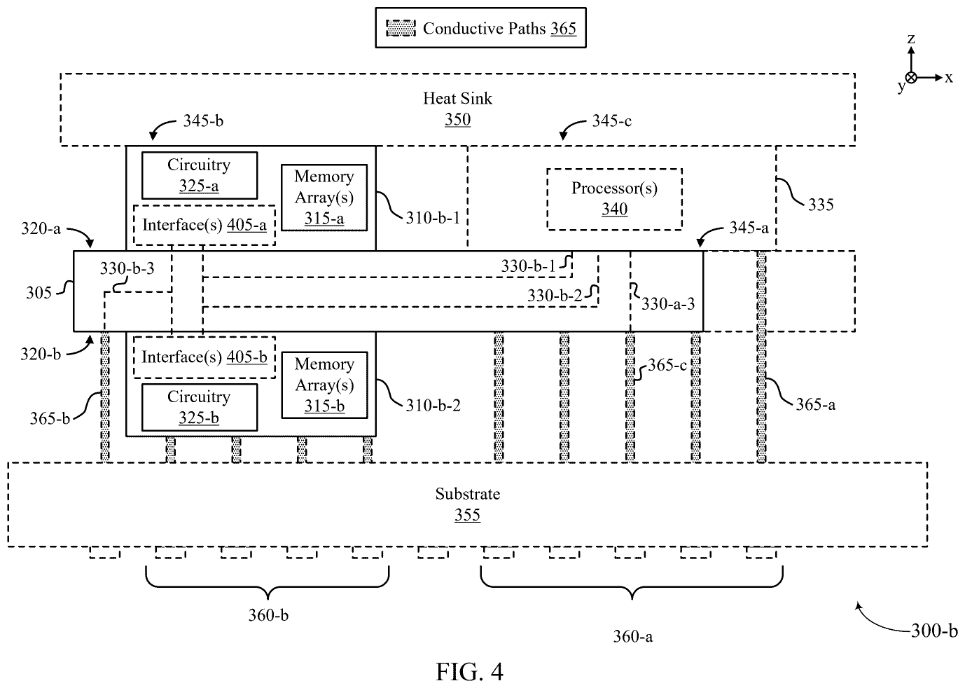

FIG. 4 shows an example of an assembly 300-b that supports interposers for double-sided memory bonding in accordance with examples as disclosed herein. The assembly 300-b may implement aspects of or be implemented by the assembly 300-a, the system 100, or the system 200, as described herein.

The assembly 300-b may include a semiconductor component 310-b-1 and a semiconductor component 310-b-2, which may be another example of aspects of semiconductor components 310 (e.g., stacks of one or more dies 240, stacks of memory devices 145, HBM stacks, HBM cores, memory stacks) and associated circuitry. Compared with the assembly 300-a, aspects of one or more of the interfaces 380 may be included within the semiconductor components 310-b. For example, the semiconductor component 310-b-1 may include one or more interfaces 405-a, and the semiconductor component 310-b-2 may include one or more interfaces 405-b.

In some examples, the interfaces 405 may include one or more physical interfaces (e.g., one or more interface blocks 245, one or more interface blocks 220, one or more logic blocks 225, channels 115) that support communications with the semiconductor component 335 via one or more physical interfaces of the semiconductor component 335 (e.g., with one or more controllers 215 of the semiconductor component 335, via one or more physical host interfaces 216). For example, the semiconductor component 335 may be coupled with the semiconductor component 310-b-1 via one or more conductive paths 330, such as a conductive path 330-b-1. Similarly, the semiconductor component 335 may be coupled with the semiconductor component 310-b-2 via one or more conductive paths 330, such as a conductive path 330-b-2. In some examples, conductive paths 330-b-1 and 330-b-2 may each be examples of one or more physical host interfaces 216.

In some examples, the interfaces 405 may be configured to provide power to a respective semiconductor component 310-b (e.g., to circuitry 325, to the one or more memory arrays 315). For example, the interfaces 405 may be coupled with the substrate 355 via one or more conductive paths 365. The interfaces 405 may receive power from one or more of the electrical contacts 360 via the one or more conductive paths 365, such as the conductive path 365-b, and via one or more conductive paths 330 of the interposer 305 (e.g., via a conductive path 330-b-3). As such, the interface 405-a may provide power to components of the semiconductor component 310-b-1, and the interface 405-b may provide power to components of the semiconductor component 310-b-2.

In some examples, for a given semiconductor component 310, an interface of the one or more interfaces 405 may be operable to access each memory array of the one or more memory arrays 315 (e.g., of a corresponding memory stack). Additionally, or alternatively, the one or more interfaces 405 may include a respective interface operable to access a respective memory array of the one or more memory arrays 315. For example, the semiconductor components 310-b may include one or more semiconductor dies, each including a respective interface of the one or more interfaces 405 and a respective memory array of the one or more memory arrays 315 (e.g., of the memory stack).

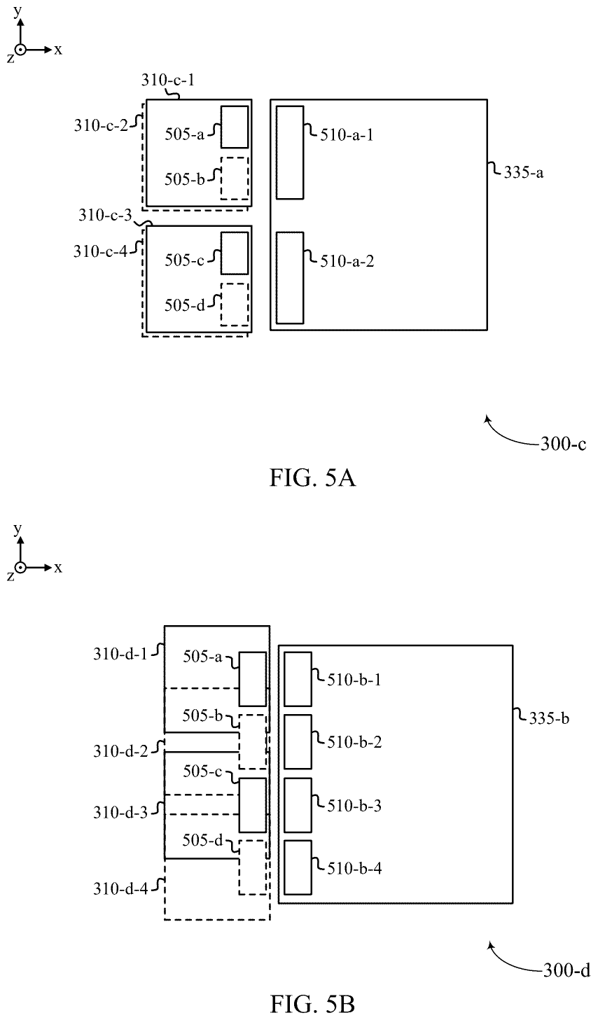

FIGS. 5A and FIG. 5B show examples of an assembly 300-c and an assembly 300-d, respectively, that support interposers for double-sided memory bonding in accordance with examples as disclosed herein. The assembly 300-c and the assembly 300-d may be examples of corresponding components (e.g., the assembly 300-a or the assembly 300-b), as described herein. The assembly 300-c and the assembly 300-d illustrate different configurations of semiconductor components 310 (e.g., semiconductor dies, memory cores, HBM cores).

The assembly 300-c illustrates a first configuration (e.g., an aligned configuration) of semiconductor components 330-c on opposite sides of an interposer 305 (not shown). For example, a semiconductor component 310-c-1 may be bonded with a first side (e.g., a side 320-a) of an interposer 305 and a semiconductor component 310-c-2 may be bonded with a second side (e.g., a side 320-b) of the interposer 305 and aligned with the semiconductor component 310-c-1 (e.g., along the x-direction, along the y-direction, or both) when viewed along the z-direction. Likewise, a semiconductor component 310-c-3 may be bonded with the first side of an interposer 305 (e.g., at a different location along the y-direction than the semiconductor component 310-c-1) and a semiconductor component 310-c-4 may be bonded with the second side of the interposer 305 (e.g., at a different location along the y-direction than the semiconductor component 310-c-2) and aligned with the semiconductor component 310-c-3 (e.g., along the x-direction, along the y-direction, or both) when viewed along the z-direction. For example, the semiconductor component 310-c-1 and the semiconductor component 310-c-3 may be located at a first level along the y-direction, and the semiconductor component 310-c-2 and the semiconductor component 310-c-4 may be located at a second level along the y-direction. Although the assembly 300-c is illustrated as including an arrangement of pairs of semiconductor components 310-c on one side of a semiconductor component 335 (e.g., along the x-direction), the described techniques may be implemented with any quantity of one or more semiconductor components 310 on a side of a semiconductor component 335 (e.g., on each side of an interposer 305), on any quantity of one or more sides of a semiconductor component 335 (e.g., along the x-direction, along the y-direction, or a combination thereof), or a combination thereof, among other variations.

Each of the semiconductor components 310-c may include physical channels 505, which may be examples of at least some of the circuitry 325 (e.g., physical interfaces, channels 115, interface blocks 245, interface blocks 220, logic blocks 225, or a combination thereof). For example, the semiconductor component 310-c-1, the semiconductor component 310-c-2, the semiconductor component 310-c-3, and the semiconductor component 310-c-4 may include physical channels 500-a, physical channels 500-b, physical channels 500-c, and physical channels 500-d, respectively. In some cases, the physical channels 505 may be offset on a surface of the semiconductor components 310 along the y-direction, such that the physical channels 500 are not overlapping in the z-direction, which may facilitate bonding or electrical interconnection with the interposer 305.

The assembly 300-c may include semiconductor component 335-a, which may include physical channels 510-a (e.g., physical host interfaces 216, controllers 215, or a combination thereof) that may be coupled with the physical channels 505 of each semiconductor component 310-c. For example, the semiconductor component 335-a may include physical channels 510-a-1 that may be coupled with the physical channels 505-a of the semiconductor component 310-c-1 and the physical channels 505-b semiconductor component 310-c-2 (e.g., via one or more conductive paths of the interposer 305). Additionally, the semiconductor component 335-a may include physical channels 510-a-2 that may be coupled with the physical channels 505-c of the semiconductor component 310-c-3 and the physical channels 505-d semiconductor component 310-c-4 (e.g., via one or more conductive paths of the interposer 305).

In some examples, the physical channels 510-a-1 of the semiconductor component 335-a may extend, along the y-direction, for a length corresponding to the length of the physical channels 505-a and the physical channels 505-b. Additionally, the physical channels 510-a-2 of the semiconductor component 335-a may extend, along the y-direction, a length corresponding to (e.g., approximately) the length of the physical channels 505-c and the physical channels 505-d. In some other examples, a semiconductor component 335 may include a respective physical channel 510 for each of the physical channels 505, or physical channels 505 of semiconductor components 310 on opposite sides of an interposer 305 may be aligned (e.g., along the x-direction, along the y-direction, or both) when viewed along the z-direction, among other implementations.

The assembly 300-d illustrates a second configuration (e.g., a staggered configuration) of semiconductor components 330-d on opposite sides of an interposer 305 (not shown). For example, a semiconductor component 310-d-1 may be bonded with a first side (e.g., a side 320-a) of an interposer 305 and a semiconductor component 310-d-2 may be bonded with a second side (e.g., a side 320-b) of the interposer 305 and offset from the semiconductor component 310-d-1 (e.g., along the y-direction) when viewed along the z-direction. Likewise, a semiconductor component 310-d-3 may be bonded with the first side of an interposer 305 (e.g., at a different location along the y-direction than the semiconductor component 310-d-1) and a semiconductor component 310-d-4 may be bonded with the second side of the interposer 305 (e.g., at a different location along the y-direction than the semiconductor component 310-d-2) and offset from the semiconductor component 310-d-3 (e.g., along the y-direction) when viewed along the z-direction. For example, the semiconductor component 310-d-1 and the semiconductor component 310-d-3 may be located at a first level along the y-direction, and the semiconductor component 310-d-2 and the semiconductor component 310-c-4 may be located at a second level along the y-direction. Although the assembly 300-d is illustrated as including an arrangement of pairs of semiconductor components 310-d on one side of a semiconductor component 335 (e.g., along the x-direction), the described techniques may be implemented with any quantity of one or more semiconductor components 310 on a side of a semiconductor component 335 (e.g., on each side of an interposer 305), on any quantity of one or more sides of a semiconductor component 335 (e.g., along the x-direction, along the y-direction, or a combination thereof), or a combination thereof, among other variations.

In some examples, the semiconductor component 310-d-1, the semiconductor component 310-d-2, the semiconductor component 310-d-3, and the semiconductor component 310-d-4 may include physical channels 505-a, physical channels 505-b, physical channels 505-c, and physical channels 505-d, respectively. In some cases, physical channels 505 of the semiconductor components 310-d may be staggered at different positions along the y-direction, such that the physical channels 505 are not overlapping when viewed along the z-direction, which may facilitate bonding or electrical interconnection with the interposer 305.

The assembly 300-d may include semiconductor component 335-b, which may include physical channels 510-b (e.g., physical host interfaces 216, controllers 215, or a combination thereof) that may be coupled with the physical channels 505 of each semiconductor component 310-d. For example, the semiconductor component 335-b may include physical channels 510-b-1 that may be coupled with the physical channels 505-a of the semiconductor component 310-d-1, physical channels 510-b-2 that may be coupled with the physical channels 505-b of the semiconductor component 310-d-2, physical channels 510-b-3 that may be coupled with the physical channels 505-c of the semiconductor component 310-d-3, and physical channels 510-b-4 that may be coupled with the physical channels 505-d of the semiconductor component 310-d-4 (e.g., via one or more conductive paths of the interposer 305). In some examples, the physical channels 510-b of the semiconductor component 335-b may be aligned with respective physical channels 505 of the semiconductor components 310-d (e.g., along the y-direction, when viewed along the x-direction).

Accordingly, by adopting an aligned configuration or a staggered configuration for stacking semiconductor components 310 on two sides of an interposer 305, a quantity of semiconductor components 310 may be effectively increased while maintaining same or similar physical dimensions (e.g., packaging) for an assembly 300.

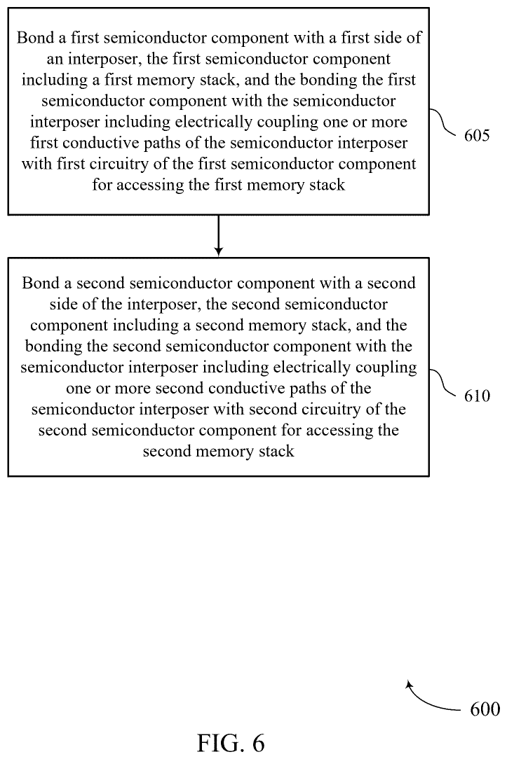

FIG. 6 shows a flowchart illustrating a method 600 that supports interposers for double-sided memory bonding in accordance with examples as disclosed herein. The operations of method 600 may be implemented by a manufacturing system or its components as described herein. For example, the operations of method 600 may be performed by a manufacturing system as described with reference to FIGS. 1 through 5. In some examples, a manufacturing system may execute a set of instructions to control the functional elements of the device to perform the described functions. Additionally, or alternatively, the manufacturing system may perform aspects of the described functions using special-purpose hardware.

At 605, the method may include bonding a first semiconductor component with a first side of an interposer, the first semiconductor component including a first memory stack, and the bonding the first semiconductor component with the interposer including electrically coupling one or more first conductive paths of the interposer with first circuitry of the first semiconductor component for accessing the first memory stack.

At 610, the method may include bonding a second semiconductor component with a second side of the interposer, the second semiconductor component including a second memory stack, and the bonding the second semiconductor component with the interposer including electrically coupling one or more second conductive paths of the interposer with second circuitry of the second semiconductor component for accessing the second memory stack.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for bonding a first semiconductor component with a first side of an interposer, the first semiconductor component including a first memory stack, and the bonding the first semiconductor component with the interposer including electrically coupling one or more first conductive paths of the interposer with first circuitry of the first semiconductor component for accessing the first memory stack and bonding a second semiconductor component with a second side of the interposer, the second semiconductor component including second memory stack, and the bonding the second semiconductor component with the interposer including electrically coupling one or more second conductive paths of the interposer with second circuitry of the second semiconductor component for accessing the second memory stack.

Aspect 2: The method, apparatus, or non-transitory computer-readable medium of aspect 1, further including operations, features, circuitry, logic, means, or instructions, or any combination thereof for bonding a third semiconductor component with the first side of the interposer, the third semiconductor component including one or more processors of a host system, and the bonding the third semiconductor component with the interposer including electrically coupling the third semiconductor component with the first semiconductor component via at least one of the one or more first conductive paths of the interposer and electrically coupling the third semiconductor component with the second semiconductor component via at least one of the one or more second conductive paths.

Aspect 3: The method, apparatus, or non-transitory computer-readable medium of aspect 2, where the interposer is bonded with an entire area of a surface of the third semiconductor component.

Aspect 4: The method, apparatus, or non-transitory computer-readable medium of any of aspects 2 through 3, where the interposer is bonded with less than an entire area of a surface of the third semiconductor component.

Aspect 5: The method, apparatus, or non-transitory computer-readable medium of any of aspects 2 through 3, further including operations, features, circuitry, logic, means, or instructions, or any combination thereof for bonding a heat sink with a surface of the first semiconductor component and a surface of the third semiconductor component.

Aspect 6: The method, apparatus, or non-transitory computer-readable medium of any of aspects 2 through 5, further including operations, features, circuitry, logic, means, or instructions, or any combination thereof for bonding the first semiconductor component, the second semiconductor component, the interposer, and the third semiconductor component with a composite conductor substrate, the bonding with the composite conductor substrate including; electrically coupling one or more first electrical contacts of the composite conductor substrate with the third semiconductor component via one or more third conductive paths of the interposer; and electrically coupling one or more second electrical contacts of the composite conductor substrate with the first semiconductor component and the second semiconductor component via one or more fourth conductive paths of the interposer.

Aspect 7: The method, apparatus, or non-transitory computer-readable medium of any of aspects 1 through 6, further including operations, features, circuitry, logic, means, or instructions, or any combination thereof for bonding a fourth semiconductor component with the first side of the interposer, the fourth semiconductor component including a third memory stack, and the bonding the fourth semiconductor component with the interposer including electrically coupling one or more third conductive paths of the interposer with third circuitry of the fourth semiconductor component for accessing the third memory stack and bonding a fifth semiconductor component with the second side of the interposer, the fifth semiconductor component including fourth memory stack, and the bonding the fifth semiconductor component with the interposer including electrically coupling one or more fourth conductive paths of the interposer with fourth circuitry of the fifth semiconductor component for accessing the fourth memory stack.

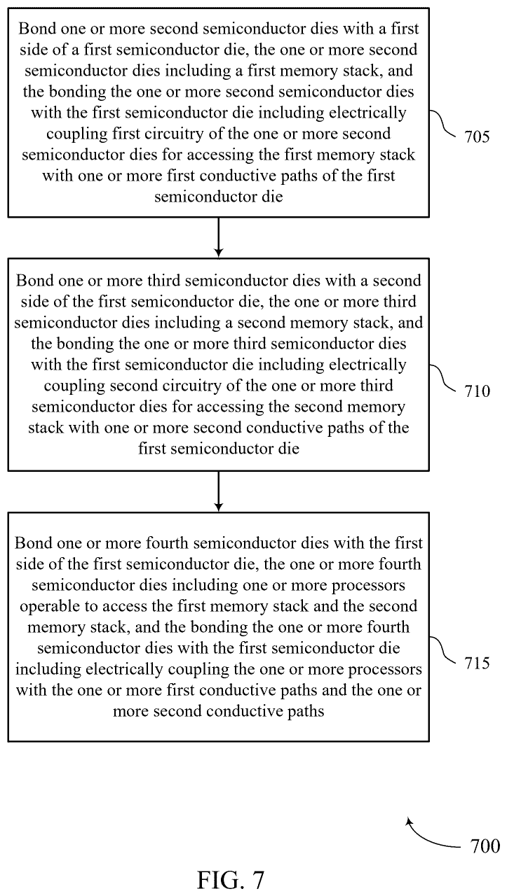

FIG. 7 shows a flowchart illustrating a method 700 that supports interposers for double-sided memory bonding in accordance with examples as disclosed herein. The operations of method 700 may be implemented by a manufacturing system or its components as described herein. For example, the operations of method 700 may be performed by a manufacturing system as described with reference to FIGS. 1 through 5. In some examples, a manufacturing system may execute a set of instructions to control the functional elements of the device to perform the described functions. Additionally, or alternatively, the manufacturing system may perform aspects of the described functions using special-purpose hardware.

At 705, the method may include bonding one or more second semiconductor dies with a first side of a first semiconductor die, the one or more second semiconductor dies including a first memory stack, and the bonding the one or more second semiconductor dies with the first semiconductor die including electrically coupling first circuitry of the one or more second semiconductor dies for accessing the first memory stack with one or more first conductive paths of the first semiconductor die.

At 710, the method may include bonding one or more third semiconductor dies with a second side of the first semiconductor die, the one or more third semiconductor dies including a second memory stack, and the bonding the one or more third semiconductor dies with the first semiconductor die including electrically coupling second circuitry of the one or more third semiconductor dies for accessing the second memory stack with one or more second conductive paths of the first semiconductor die.

At 715, the method may include bonding one or more fourth semiconductor dies with the first side of the first semiconductor die, the one or more fourth semiconductor dies including one or more processors operable to access the first memory stack and the second memory stack, and the bonding the one or more fourth semiconductor dies with the first semiconductor die including electrically coupling the one or more processors with the one or more first conductive paths and the one or more second conductive paths.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 8: A method, apparatus, or non-transitory computer-readable medium including operations, features, circuitry, logic, means, or instructions, or any combination thereof for bonding one or more second semiconductor dies with a first side of a first semiconductor die, the one or more second semiconductor dies including a first memory stack, and the bonding the one or more second semiconductor dies with the first semiconductor die including electrically coupling first circuitry of the one or more second semiconductor dies for accessing the first memory stack with one or more first conductive paths of the first semiconductor die; bonding one or more third semiconductor dies with a second side of the first semiconductor die, the one or more third semiconductor dies including a second memory stack, and the bonding the one or more third semiconductor dies with the first semiconductor die including electrically coupling second circuitry of the one or more third semiconductor dies for accessing the second memory stack with one or more second conductive paths of the first semiconductor die; and bonding one or more fourth semiconductor dies with the first side of the first semiconductor die, the one or more fourth semiconductor dies including one or more processors operable to access the first memory stack and the second memory stack, and the bonding the one or more fourth semiconductor dies with the first semiconductor die including electrically coupling the one or more processors with the one or more first conductive paths and the one or more second conductive paths.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 9: A system, including: an interposer; a first semiconductor component including a first memory stack, the first semiconductor component bonded with a first side of the interposer and including first circuitry that is electrically coupled with one or more first conductive paths of the interposer; and a second semiconductor component including second memory stack, the second semiconductor component bonded with a second side of the interposer, opposite the first side, and including second circuitry that is electrically coupled with one or more second conductive paths of the interposer.

Aspect 10: The system of aspect 9, further including: a third semiconductor component including one or more processors, the third semiconductor component bonded with the first side of the interposer, the one or more processors coupled with the first semiconductor component via at least one of the one or more first conductive paths of the interposer and coupled with the second semiconductor component via at least one of the one or more second conductive paths.

Aspect 11: The system of aspect 10, where, along a direction of separation between the first semiconductor component and the third semiconductor component, the interposer extends farther from the first semiconductor component than the third semiconductor component.

Aspect 12: The system of any of aspect 10, where, along a direction of separation between the first semiconductor component and the third semiconductor component, the third semiconductor component extends farther from the first semiconductor component than the interposer.

Aspect 13: The system of any of aspects 10 through 12, where the interposer is bonded with an entire area of a surface of the third semiconductor component.

Aspect 14: The system of any of aspects 10 through 12, where the interposer is bonded with less than an entire area of a surface of the third semiconductor component.

Aspect 15: The system of any of aspects 10 through 14, where a first surface of the first semiconductor component opposite the interposer is coplanar with a second surface of the third semiconductor component opposite the interposer.

Aspect 16: The system of aspect 15, further including: a heat sink bonded with the first surface of the first semiconductor component and the second surface of the third semiconductor component.

Aspect 17: The system of any of aspects 10 through 16, further including: a composite conductor substrate including: one or more first electrical contacts coupled with the third semiconductor component via one or more third conductive paths of the interposer; and one or more second electrical contacts coupled with the first semiconductor component and the second semiconductor component via one or more fourth conductive paths of the interposer.

Aspect 18: The system of aspect 17, where the third semiconductor component is coupled with the composite conductor substrate via one or more fifth conductive paths that do not intersect the interposer.

Aspect 19: The system of any of aspects 17 through 18, where the second semiconductor component is located between the interposer and the composite conductor substrate.

Aspect 20: The system of any of aspects 17 through 19, where: at least one of the one or more third conductive paths is configured to communicate information signaling between the third semiconductor component and the composite conductor substrate; at least one of the one or more third conductive paths is configured to provide power to the third semiconductor component via the composite conductor substrate; and at least one of the one or more fourth conductive paths is configured to provide power to the first semiconductor component and the second semiconductor component via the composite conductor substrate.

Aspect 21: The system of any of aspects 10 through 20, where the third semiconductor component includes one or more semiconductor dies including one or more processors of a host system.

Aspect 22: The system of any of aspects 10 through 21, where: at least one of the first conductive paths of the interposer is associated with one or more first physical host interfaces between the third semiconductor component and the first semiconductor component; and at least one of the second conductive paths of the interposer is associated with one or more second physical host interfaces between the third semiconductor component and the second semiconductor component.

Aspect 23: The system of any of aspects 10 through 22, where the first and second semiconductor components are bonded with the interposer along a same direction from the third semiconductor component.

Aspect 24: The system of any of aspects 9 through 23, where the interposer includes interface circuitry operable to access the first memory stack and the second memory stack.

Aspect 25: The system of any of aspects 9 through 24, where: the first semiconductor component includes: one or more first semiconductor dies each including a respective first memory array of the first memory stack; and a second semiconductor die including first interface circuitry operable to access the respective first memory array; and the second semiconductor component includes: one or more third semiconductor dies each including a respective second memory array of the second memory stack; and a fourth semiconductor die including second interface circuitry operable to access the respective second memory array.

Aspect 26: The system of any of aspects 9 through 25, further including: a fourth semiconductor component including a third memory stack, the fourth semiconductor component bonded with the first side of the interposer and electrically coupled with one or more third conductive paths of the interposer; and a fifth semiconductor component including a fourth memory stack, the fifth semiconductor component bonded with the second side of the interposer and electrically coupled with one or more fourth conductive paths of the interposer.

Aspect 27: The system of aspect 26, where, when viewed along a direction through the interposer: the first semiconductor component is aligned with the second semiconductor component; and the fourth semiconductor component is aligned with the fifth semiconductor component.

Aspect 28: The system of any of aspect 26, where, when viewed along a direction through the interposer: the first semiconductor component and the second semiconductor component are staggered along a direction over the interposer; and the fourth semiconductor component and the fifth semiconductor component are staggered along the direction over the interposer.

An apparatus is described. The following provides an overview of aspects of the apparatus as described herein:

Aspect 29: A system, including: a first semiconductor die; one or more second semiconductor dies including a first memory stack, the one or more second semiconductor dies bonded with a first side of the first semiconductor die and electrically coupled with one or more first conductive paths of the first semiconductor die; one or more third semiconductor dies including a second memory stack, the one or more third semiconductor dies bonded with a second side of the first semiconductor die and electrically coupled with one or more second conductive paths of the first semiconductor die; and one or more fourth semiconductor dies including one or more processors operable to access the first memory stack and the second memory stack, the one or more fourth semiconductor dies bonded with the first side of the first semiconductor die and electrically coupled with the one or more first conductive paths and the one or more second conductive paths.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to condition of moving from an open-circuit relationship between components in which signals are not presently capable of being communicated between the components (e.g., over a conductive path) to a closed-circuit relationship between components in which signals are capable of being communicated between components (e.g., over the conductive path). When a component, such as a controller, couples other components together, the component may initiate a change that allows signals to flow between the other components over a conductive path that previously did not permit signals to flow.

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A system, comprising:
an interposer;
a first semiconductor component comprising a first memory stack, the first semiconductor component bonded with a first side of the interposer and including first circuitry that is electrically coupled with one or more first conductive paths of the interposer; and
a second semiconductor component comprising a second memory stack, the second semiconductor component bonded with a second side of the interposer, opposite the first side, and including second circuitry that is electrically coupled with one or more second conductive paths of the interposer.

2. The system of claim 1, further comprising:
a third semiconductor component comprising one or more processors, the third semiconductor component bonded with the first side of the interposer, the one or more processors coupled with the first semiconductor component via at least one of the one or more first conductive paths of the interposer and coupled with the second semiconductor component via at least one of the one or more second conductive paths.

3. The system of claim 2, wherein, along a direction of separation between the first semiconductor component and the third semiconductor component, the interposer extends farther from the first semiconductor component than the third semiconductor component.

4. The system of claim 2, wherein, along a direction of separation between the first semiconductor component and the third semiconductor component, the third semiconductor component extends farther from the first semiconductor component than the interposer.

5. The system of claim 2, wherein the interposer is bonded with an entire area of a surface of the third semiconductor component.

6. The system of claim 2, wherein the interposer is bonded with less than an entire area of a surface of the third semiconductor component.

7. The system of claim 2, wherein a first surface of the first semiconductor component opposite the interposer is coplanar with a second surface of the third semiconductor component opposite the interposer.

8. The system of claim 7, further comprising:
a heat sink bonded with the first surface of the first semiconductor component and the second surface of the third semiconductor component.

9. The system of claim 2, further comprising:
a composite conductor substrate comprising:
one or more first electrical contacts coupled with the third semiconductor component via one or more third conductive paths of the interposer; and
one or more second electrical contacts coupled with the first semiconductor component and the second semiconductor component via one or more fourth conductive paths of the interposer.

10. The system of claim 9, wherein the third semiconductor component is coupled with the composite conductor substrate via one or more fifth conductive paths that do not intersect the interposer.

11. The system of claim 9, wherein the second semiconductor component is located between the interposer and the composite conductor substrate.

12. The system of claim 9, wherein:
at least one of the one or more third conductive paths is configured to communicate information signaling between the third semiconductor component and the composite conductor substrate;
at least one of the one or more third conductive paths is configured to provide power to the third semiconductor component via the composite conductor substrate; and
at least one of the one or more fourth conductive paths is configured to provide power to the first semiconductor component and the second semiconductor component via the composite conductor substrate.

13. The system of claim 2, wherein the third semiconductor component comprises one or more semiconductor dies including one or more processors of a host system.

14. The system of claim 2, wherein:
at least one of the first conductive paths of the interposer is associated with one or more first physical host interfaces between the third semiconductor component and the first semiconductor component; and
at least one of the second conductive paths of the interposer is associated with one or more second physical host interfaces between the third semiconductor component and the second semiconductor component.

15. The system of claim 2, wherein the first and second semiconductor components are bonded with the interposer along a same direction from the third semiconductor component.

16. The system of claim 1, wherein the interposer comprises interface circuitry operable to access the first memory stack and the second memory stack.

17. The system of claim 1, wherein:
the first semiconductor component comprises:
one or more first semiconductor dies each including a respective first memory array of the first memory stack; and
a second semiconductor die including first interface circuitry operable to access the respective first memory array; and
the second semiconductor component comprises:
one or more third semiconductor dies each including a respective second memory array of the second memory stack; and
a fourth semiconductor die including second interface circuitry operable to access the respective second memory array.

18. The system of claim 1, further comprising:
a fourth semiconductor component comprising a third memory stack, the fourth semiconductor component bonded with the first side of the interposer and electrically coupled with one or more third conductive paths of the interposer; and
a fifth semiconductor component comprising a fourth memory stack, the fifth semiconductor component bonded with the second side of the interposer and electrically coupled with one or more fourth conductive paths of the interposer.

19. The system of claim 18, wherein, when viewed along a direction through the interposer:
the first semiconductor component is aligned with the second semiconductor component; and
the fourth semiconductor component is aligned with the fifth semiconductor component.

20. The system of claim 18, wherein, when viewed along a direction through the interposer:
the first semiconductor component and the second semiconductor component are staggered along a direction over the interposer; and
the fourth semiconductor component and the fifth semiconductor component are staggered along the direction over the interposer.

21. A method, comprising:
bonding a first semiconductor component with a first side of an interposer, the first semiconductor component comprising a first memory stack, and the bonding the first semiconductor component with the interposer comprising electrically coupling one or more first conductive paths of the interposer with first circuitry of the first semiconductor component for accessing the first memory stack; and
bonding a second semiconductor component with a second side of the interposer, the second semiconductor component comprising second memory stack, and the bonding the second semiconductor component with the interposer comprising electrically coupling one or more second conductive paths of the interposer with second circuitry of the second semiconductor component for accessing the second memory stack.

22. The method of claim 21, further comprising:
bonding a third semiconductor component with the first side of the interposer, the third semiconductor component comprising one or more processors of a host system, and the bonding the third semiconductor component with the interposer comprising electrically coupling the third semiconductor component with the first semiconductor component via at least one of the one or more first conductive paths of the interposer and electrically coupling the third semiconductor component with the second semiconductor component via at least one of the one or more second conductive paths.

23. The method of claim 22, wherein the interposer is bonded with an entire area of a surface of the third semiconductor component.

24. The method of claim 22, wherein the interposer is bonded with less than an entire area of a surface of the third semiconductor component.

25. The method of claim 22, further comprising:
bonding a heat sink with a surface of the first semiconductor component and a surface of the third semiconductor component.

26. The method of claim 22, further comprising:
bonding the first semiconductor component, the second semiconductor component, the interposer, and the third semiconductor component with a composite conductor substrate, the bonding with the composite conductor substrate comprising:
electrically coupling one or more first electrical contacts of the composite conductor substrate with the third semiconductor component via one or more third conductive paths of the interposer; and
electrically coupling one or more second electrical contacts of the composite conductor substrate with the first semiconductor component and the second semiconductor component via one or more fourth conductive paths of the interposer.

27. The method of claim 21, further comprising:
bonding a fourth semiconductor component with the first side of the interposer, the fourth semiconductor component comprising third memory stack, and the bonding the fourth semiconductor component with the interposer comprising electrically coupling one or more third conductive paths of the interposer with third circuitry of the fourth semiconductor component for accessing the third memory stack; and
bonding a fifth semiconductor component with the second side of the interposer, the fifth semiconductor component comprising fourth memory stack, and the bonding the fifth semiconductor component with the interposer comprising electrically coupling one or more fourth conductive paths of the interposer with fourth circuitry of the fifth semiconductor component for accessing the fourth memory stack.

28. A system formed by a process comprising:
bonding a first semiconductor component with a first side of an interposer, the first semiconductor component comprising first memory stack, and the bonding the first semiconductor component with the interposer comprising electrically coupling one or more first conductive paths of the interposer with first circuitry of the first semiconductor component for accessing the first memory stack; and
bonding a second semiconductor component with a second side of the interposer, the second semiconductor component comprising second memory stack, and the bonding the second semiconductor component with the interposer comprising electrically coupling one or more second conductive paths of the interposer with second circuitry of the second semiconductor component for accessing the second memory stack.

29. A system, comprising:
a first semiconductor die;
one or more second semiconductor dies comprising first memory stack, the one or more second semiconductor dies bonded with a first side of the first semiconductor die and electrically coupled with one or more first conductive paths of the first semiconductor die;
one or more third semiconductor dies comprising second memory stack, the one or more third semiconductor dies bonded with a second side of the first semiconductor die and electrically coupled with one or more second conductive paths of the first semiconductor die; and
one or more fourth semiconductor dies comprising one or more processors operable to access the first memory stack and the second memory stack, the one or more fourth semiconductor dies bonded with the first side of the first semiconductor die and electrically coupled with the one or more first conductive paths and the one or more second conductive paths.

30. A method, comprising:
bonding one or more second semiconductor dies with a first side of a first semiconductor die, the one or more second semiconductor dies comprising first memory stack, and the bonding the one or more second semiconductor dies with the first semiconductor die comprising electrically coupling first circuitry of the one or more second semiconductor dies for accessing the first memory stack with one or more first conductive paths of the first semiconductor die;
bonding one or more third semiconductor dies with a second side of the first semiconductor die, the one or more third semiconductor dies comprising second memory stack, and the bonding the one or more third semiconductor dies with the first semiconductor die comprising electrically coupling second circuitry of the one or more third semiconductor dies for accessing the second memory stack with one or more second conductive paths of the first semiconductor die; and
bonding one or more fourth semiconductor dies with the first side of the first semiconductor die, the one or more fourth semiconductor dies comprising one or more processors operable to access the first memory stack and the second memory stack, and the bonding the one or more fourth semiconductor dies with the first semiconductor die comprising electrically coupling the one or more processors with the one or more first conductive paths and the one or more second conductive paths.
